(19) United States
(12) Patent Application Publication
(10) Pub. No.: US 2024/0260436 A1
(43) Pub. Date: Aug. 1, 2024

(54) DISPLAY PANEL AND MANUFACTURING METHOD OF THE SAME

(71) Applicant: Samsung Display Co., Ltd., Yongin-si (KR)

(72) Inventors: GUNSHIK KIM, Yongin-si (KR); DAEYONG KIM, Yongin-si (KR); JUNG KI SHIN, Yongin-si (KR); JONGHYEON LEE, Yongin-si (KR); MEEHYE JUNG, Yongin-si (KR)

(73) Assignee: Samsung Display Co., Ltd., Yongin-si (KR)

(21) Appl. No.: 18/526,110

(22) Filed: Dec. 1, 2023

(30) Foreign Application Priority Data
Jan. 31, 2023 (KR) 10-2023-0012798

(51) Int. Cl. H10K 59/80; H10K 59/122; H10K 59/95; H10K 71/40; H10K 71/60

(52) U.S. Cl. CPC H10K 59/8794; H10K 59/122; H10K 59/95; H10K 71/40; H10K 71/60

(57) ABSTRACT

A display panel includes a pixel region and a non-pixel region adjacent to the pixel region, and a light-emitting element layer disposed on a base layer. The light-emitting element layer includes a first electrode disposed on the base layer, a pixel defining film disposed on the base layer and having pixel openings corresponding to the pixel region, a heating line disposed on the pixel defining film, an organic layer including a light-emitting layer and disposed on the first electrode, and a second electrode disposed on the organic layer. The heating line is disposed in the non-pixel region and surrounds the pixel region in a plan view, thereby improving reliability and processability.

### CROSS-REFERENCE TO RELATED APPLICATIONS

This application claims priority to and benefits of Korean Patent Application No. 10-2023-0012798 under 35 U.S.C. § 119, filed on Jan. 31, 2023, in the Korean Intellectual Property Office (KIPO), the entire contents of which are incorporated herein by reference.

### BACKGROUND

### 1. Technical Field

The disclosure herein relates to a display panel with improved reliability and processability and a method for manufacturing the same.

### 2. Description of the Related Art

Electronic devices, such as smart phones, tablets, digital cameras, notebook computers, navigation systems, and televisions, which provide an image to a user, include a display device for displaying an image.

In the display device, pixels may be divided into red, green, and blue pixels for color display, and a light-emitting layer may be formed for each pixel according to the color of each corresponding pixel. In general, a deposition method using a shadow mask is used for the light-emitting layer, but a defect such as mask sagging may occur. Therefore, a process of forming the light-emitting layer and other organic layers in common for all pixels through an open mask has been developed.

However, in case that an organic layer is formed in common, a lateral leakage current may occur between adjacent pixels due to a commonly provided organic layer, and because of this, defects such as poor luminance and color mixing between adjacent pixels may occur.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

The disclosure provides a display panel with improved reliability by preventing defects such as poor luminance and color mixing between adjacent pixels.

The disclosure also provides a display panel manufacturing method with improved processability.

According to an embodiment of the disclosure, a display panel may include a pixel region and a non-pixel region adjacent to the pixel region, and a light-emitting element layer disposed on a base layer. The light-emitting element layer may include a first electrode disposed on the base layer, a pixel defining film disposed on the base layer and having pixel openings corresponding to the pixel region, a heating line disposed on the pixel defining film, an organic layer including a light-emitting layer and disposed on the first electrode, and a second electrode disposed on the organic layer. The heating line may be disposed in the non-pixel region and may surround the pixel region in a plan view.

In an embodiment, the pixel region may include a first pixel region and a second pixel region adjacent to the first pixel region. The first pixel region and the second pixel region may be spaced apart from each other with the heating line interposed between the first pixel region and the second pixel region.

In an embodiment, the heating line may include a first portion having a first width and a second portion having a second width greater than the first width. The first portion of the heating line may contact and be electrically connected to the second electrode.

In an embodiment, the organic layer may include a first organic layer and a second organic layer disposed on the first organic layer. In a plan view, the heating line may be spaced apart from the first organic layer and covered by the second organic layer.

In an embodiment, in a plan view, the heating line may be spaced apart from the organic layer, and the heating line may contact and be electrically connected to the second electrode.

In an embodiment, in a plan view, the heating line may be spaced apart from the organic layer, the heating line may contact and be electrically connected to the second electrode, the organic layer may include a first organic layer and a second organic layer disposed on the first organic layer, and the first organic layer may be covered by the second organic layer.

In an embodiment, the heating line may include a first portion having a first width and a second portion having a second width greater than the first width, the organic layer may include a first organic layer and a second organic layer disposed on the first organic layer, the first portion of the heating line may contact and be electrically connected to the second electrode, and in a plan view, the second portion of the heating line may be spaced apart from the first organic layer and covered by the second organic layer.

In an embodiment, in a plan view, the first portion of the heating line is spaced apart from the first organic layer and the second organic layer.

In an embodiment, the non-pixel region may include a first region in which the heating line is disposed at a high density and a second region in which the heating line is disposed at a low density. The heating line disposed in the first region may contact and be electrically connected to the second electrode.

In an embodiment, the heating line may contain a metal.

In an embodiment, the base layer may include a glass substrate or a silicon (Si) substrate.

In an embodiment, a width of each of the pixel openings may be in a range of about 1 μm to about 2 μm, and a width of the heating line may be in a range of about 0.1 μm to about 0.3 μm.

In an embodiment of the disclosure, a method for manufacturing a display panel may include: preparing a preliminary display panel including a pixel region and a non-pixel region adjacent to the pixel region and including a base layer, a first electrode disposed on the base layer, a pixel defining film disposed on the base layer and having pixel openings corresponding to the pixel region, and a heating line surrounding the pixel region and disposed on the pixel defining film; forming an organic layer including a light-emitting layer on the preliminary display panel; applying a voltage to the heating line and removing at least a portion of the organic layer adjacent to the heating line by generated heat; and forming a second electrode on the organic layer.

In an embodiment, the pixel region may include a first pixel region and a second pixel region adjacent to the first pixel region. The first pixel region and the second pixel region may be spaced apart from each other with the heating line interposed between the first pixel region and the second pixel region.

In an embodiment, the heating line may include a first portion having a first width and a second portion having a second width greater than the first width, and the removing of the at least a portion of the organic layer may include removing the organic layer adjacent to the first portion of the heating line.

In an embodiment, the forming of the organic layer may include forming a first organic layer and forming a second organic layer, the removing of the at least a portion of the organic layer may include removing at least a portion of the first organic layer adjacent to the heating line after the forming of the first organic layer, and the forming of the second organic layer may be performed after the removing of the at least a portion of the first organic layer.

In an embodiment, the removing of the at least a portion of the organic layer may include removing all of the organic layer adjacent to the heating line, and after the forming of the second electrode, the second electrode may contact all of the heating line.

In an embodiment, the forming of the organic layer may include forming a first organic layer and forming a second organic layer, the removing of the at least a portion of the organic layer may include removing the first organic layer adjacent to the heating line and removing the second organic layer adjacent to the heating line, the removing of the first organic layer may include applying a first pulse voltage after the forming of the first organic layer, the forming of the second organic layer may be performed after the applying of the first pulse voltage, the removing of the second organic layer may include applying a second pulse voltage after the forming of the second organic layer, and a pulse width of the first pulse voltage may be greater than a pulse width of the second pulse voltage.

In an embodiment, the heating line may include a first portion having a first width and a second portion having a second width greater than the first width, the forming of the organic layer may include forming a first organic layer and forming a second organic layer, the removing of the at least a portion of the organic layer may include removing the first organic layer adjacent to the first portion and the second portion of the heating line and removing the second organic layer adjacent to the first portion of the heating line, the removing of the first organic layer adjacent to the first portion and the second portion of the heating line may include applying a first pulse voltage after the forming of the first organic layer, the forming of the second organic layer may be performed after the applying of the first pulse voltage, the removing of the second organic layer adjacent to the first portion of the heating line may include applying a second pulse voltage after the forming of the second organic layer, and a voltage of the first pulse voltage may be higher than a voltage of the second pulse voltage.

In an embodiment, the non-pixel region may include a first region in which the heating line is disposed at a high density and a second region in which the heating line is disposed at a low density, and the removing of the at least a portion of the organic layer may include removing the organic layer adjacent to the heating line disposed in the first region.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a combined perspective view of a display device according to an embodiment of the disclosure;

FIG. 2 is an exploded perspective view of the display device according to an embodiment of the disclosure;

FIG. 3 is a schematic cross-sectional view of a display module according to an embodiment of the disclosure;

FIG. 4 is a schematic cross-sectional view of a portion of a display panel according to an embodiment of the disclosure;

FIGS. 5A to 5C are each a schematic cross-sectional view of a light-emitting element according to an embodiment of the disclosure;

FIGS. 6A to 6D are each a plan view of a portion of the display panel according to an embodiment of the disclosure;

FIG. 7A is a schematic cross-sectional view of a portion of the display panel according to an embodiment of the disclosure;

FIG. 7B is a perspective view schematically illustrating a heating line and a heating pad according to an embodiment of the disclosure;

FIG. 8A is a schematic cross-sectional view of a portion of the display panel according to an embodiment of the disclosure;

FIG. 8B is a perspective view schematically illustrating a heating line and a heating pad according to an embodiment of the disclosure;

FIG. 9A is a schematic cross-sectional view of a portion of the display panel according to an embodiment of the disclosure;

FIG. 9B is a perspective view schematically illustrating a heating line and a heating pad according to an embodiment of the disclosure;

FIG. 10A is a schematic cross-sectional view of a portion of the display panel according to an embodiment of the disclosure;

FIG. 10B is a perspective view schematically illustrating a heating line and a heating pad according to an embodiment of the disclosure;

FIGS. 11A and 11B are each a schematic cross-sectional view of a portion of the display panel according to an embodiment of the disclosure;

FIG. 11C is a perspective view schematically illustrating a heating line and a heating pad according to an embodiment of the disclosure;

FIG. 12 is a plan view of a portion of the display panel according to an embodiment of the disclosure;

FIG. 13A is a perspective view schematically illustrating a portion of the display panel according to an embodiment of the disclosure;

FIG. 13B is a graph obtained by measuring the temperatures of a heating line and a peripheral portion according to an embodiment of the disclosure;

FIG. 13C is a graph obtained by measuring the temperatures of a peripheral portion of the heating line according to an embodiment of the disclosure;

FIG. 14 is a graph obtained by measuring the temperatures of a heating line and a peripheral portion according to an embodiment of the disclosure;

FIG. 15 is a flowchart of a method of manufacturing the display panel according to an embodiment of the disclosure; and

FIGS. 16 to 18 are each a schematic cross-sectional view illustrating one step of the method of manufacturing the display panel according to an embodiment of the disclosure.

### DETAILED DESCRIPTION OF THE EMBODIMENTS

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Meanwhile, in the application, being “directly disposed” may mean that there is no layer, film, region, plate, or the like added between a part such as a layer, film, region, or plate and another part such as a layer, film, region, or plate. For example, being “directly disposed” may mean that no additional member such as an adhesive member is disposed between two layers or two members.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Like reference numerals, reference characters, and reference symbols refer to like elements.

As used herein, the term “and/or” includes any and all combinations that the associated configurations can define. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms first, second, etc. may be used herein to describe various elements, these elements should not be limited by these terms. These terms are used to distinguish one element from another element. For example, a first element could be termed a second element without departing from the scope of the disclosure. Similarly, the second element may also be referred to as the first element. The terms of a singular form include plural forms unless otherwise specified.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel and a manufacturing method thereof according to an embodiment of the disclosure are described with reference to the drawings.

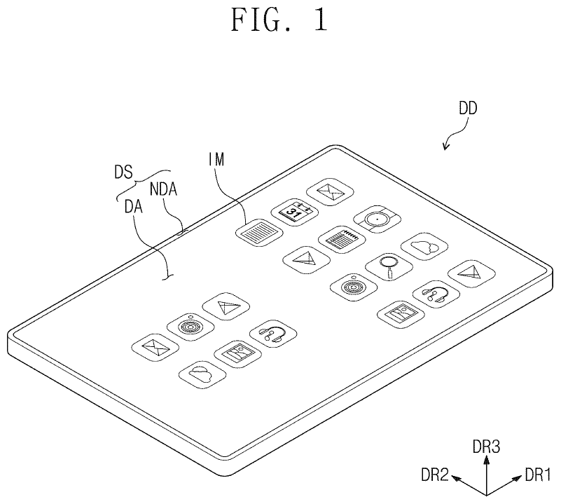

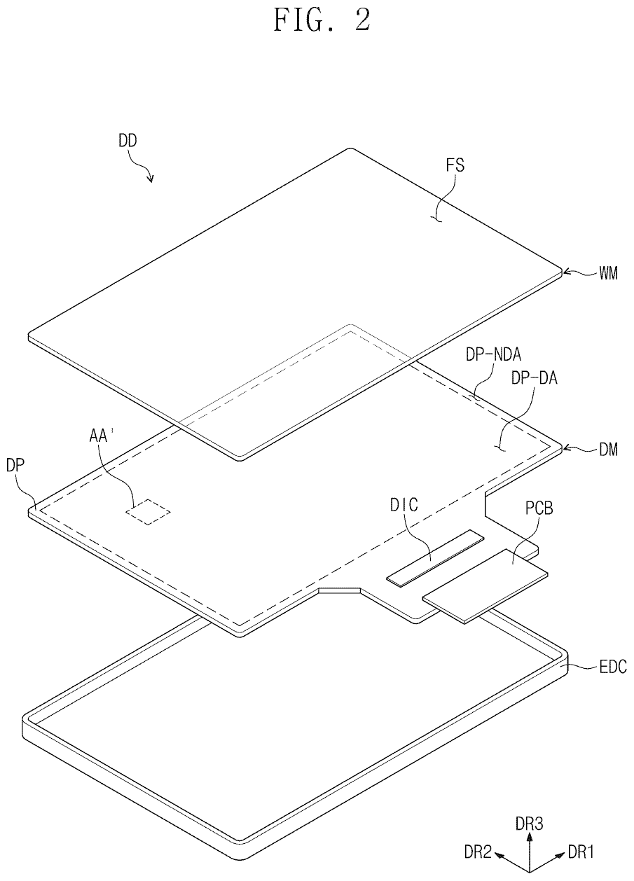

FIG. 1 is a combined perspective view of a display device DD according to an embodiment of the disclosure. FIG. 2 is an exploded perspective view of the display device DD according to an embodiment of the disclosure.

Referring to FIG. 1, the display device DD may be activated according to an electrical signal. The display device DD may display an image IM and sense an external input. The display device DD may include various embodiments. For example, the display device DD may be a mobile phone (smartphone), a tablet, a monitor, a laptop computer, a television, an external billboard, a car navigation system, a game machine, a camera, or a wearable device, but the embodiment of the disclosure is not limited thereto. In the specification, a tablet is described as an embodiment of the display device DD.

FIG. 1 and the following drawings illustrate a first direction DR1, a second direction DR2, and a third direction DR3, and directions indicated by the first to third directions DR1, DR2, and DR3 described in this specification are relative concepts and may be converted into other directions. In this specification, the first direction DR1 and the second direction DR2 may be orthogonal to each other, and the third direction DR3 may be a normal direction to a plane defined by the first and second directions DR1 and DR2. In this specification, the expression “on a plane” may mean a plane defined by the first and second directions DR1 and

DR2.

In this specification, the thickness direction of the display device DD may be parallel to the third direction DR3 which is a normal direction to a plane defined by the first and second directions DR1 and DR2. The front surface (or upper surface) and rear surface (or lower surface) of members constituting the display device DD may be defined based on the third direction DR3.

The display device DD may include a display region DA and a non-display region NDA adjacent to the display region DA. The display region DA may be surrounded by the non-display region NDA. However, the disclosure is not limited thereto. For example, the non-display region NDA may be disposed adjacent to only a side of the display region DA.

The display device DD may display an image IM in the third direction DR3 on a display surface DS parallel to each of the first and second directions DR1 and DR2. The display surface DS on which an image IM is displayed may correspond to the front surface of the display device DD and may correspond to the front surface FS of the window WM. Hereinafter, a same reference numeral will be used for the display surface, the front surface of the display device DD, and the front surface of the window WM. The image IM may include a still image as well as a moving image. FIG. 1 illustrates multiple icons as an example of the image IM.

The display device DD according to an embodiment of the disclosure may sense a user's input applied from the outside. A user's input may include various types of external inputs, such as a part of the user's body, light, heat, or pressure. The user's input may be provided in various forms, and the display device DD may sense the user's input applied to a side or rear surface of the display device DD according to the structure of the display device DD, and the disclosure is not limited thereto.

As illustrated in FIG. 2, the display device DD may include a window WM, a display module DM, and an outer case EDC. In an embodiment, the window WM and the outer case EDC may be coupled to each other to form the exterior of the display device DD. In an embodiment, the outer case EDC, the display module DM, and the window WM may be sequentially stacked in the third direction DR3.

The window WM may contain an optically transparent material. The window WM may include an insulating panel. For example, the window WM may be made of glass, plastic, or a combination thereof.

The front surface FS of the window WM may define the front surface of the display device DD.

The window WM may include a bezel region and a transmission region. The transmission region may be an optically transparent region. For example, the transmission region may be a region having a visible light transmittance of greater than or equal to about 90%.

The bezel region may have a relatively low light transmittance compared to the transmission region. The bezel region may define the shape of the transmission region. The bezel region may be adjacent to and surround the transmission region. The bezel region may have a color. The bezel region may overlap the non-display region DP-NDA of the display panel DP in a plan view. The bezel region may cover the non-display region DP-NDA of the display panel DP and block the non-display region DP-NDA from being viewed from the outside. However, the disclosure is not limited thereto, and the bezel region of the window WM may be omitted.

The display module DM may include a display panel DP. FIG. 2 illustrates only the display panel DP in the stacked structure of the display module DM, but the display module DM may further include multiple structures disposed above and/or below the display panel DP. A detailed description of the stacked structure of the display module DM is provided below.

The display panel DP may include a display region DP-DA and a non-display region DP-NDA respectively corresponding to the display region DA and the non-display region NDA of the display device DD. In this specification, the expression “a region/portion corresponds to another region/portion” means that the regions/portions overlap each other, but the expression is not limited to having a same area. The display module DM may include a driving chip DIC disposed in the non-display region DP-NDA. The display module DM may further include a printed circuit board PCB disposed in the non-display region DP-NDA. The printed circuit board PCB may be electrically connected to pads disposed in the non-display region DP-NDA of the display panel DP by an anisotropic conductive adhesive layer.

The driving chip DIC may include driving elements for driving pixels of the display panel DP, for example, a data driving circuit. Although FIG. 2 illustrates that the driving chip DIC is mounted on the display panel DP, the disclosure is not limited thereto. For example, the driving chip DIC may be mounted on the printed circuit board PCB.

The outer case EDC may accommodate the display module DM and be coupled to the window WM. The outer case EDC may protect elements accommodated therein, such as the display module DM.

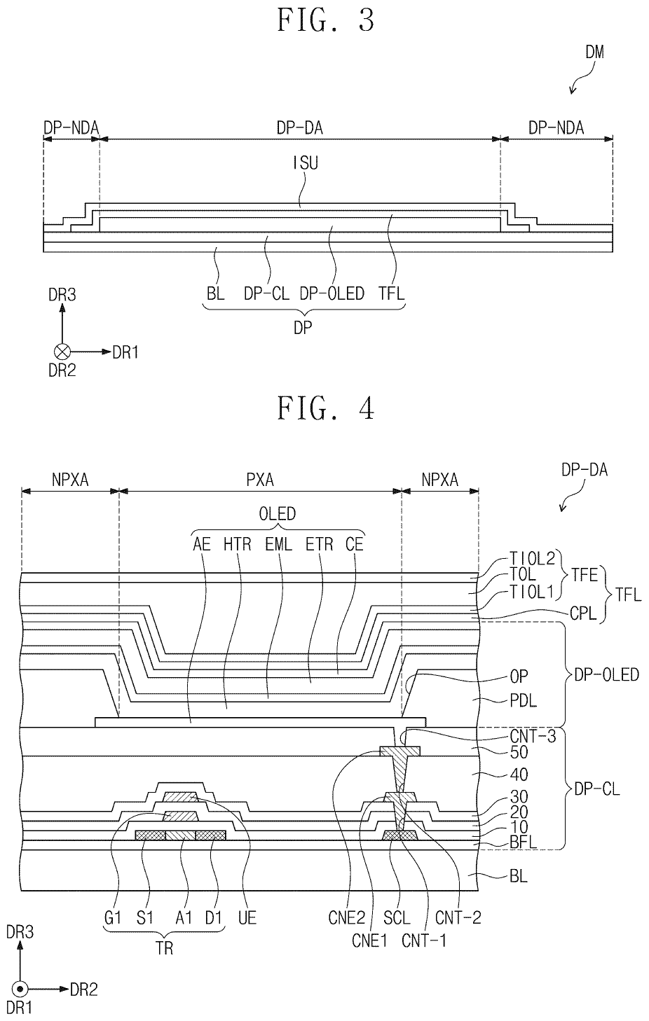

FIG. 3 is a schematic cross-sectional view of the display module DM according to an embodiment of the disclosure. FIG. 4 is a schematic cross-sectional view of a portion of the display panel DP according to an embodiment of the disclosure. FIG. 4 schematically illustrates a light-emitting element OLED and a transistor TR for a pixel included in the display region DP-DA of the display panel DP according to an embodiment of the disclosure.

Referring to FIG. 3, the display module DM may include a display panel DP and an input sensing unit ISU. The display panel DP may substantially generate an image IM (see FIG. 1). The image IM (see FIG. 1) generated by the display panel DP may be viewed by a user from the outside through the display region DA (see FIG. 1).

The display panel DP may be a light-emitting display panel but is not particularly limited thereto. For example, the display panel DP may be an organic light-emitting display panel or an inorganic light-emitting display panel. The organic light-emitting display panel may be a display panel in which a light-emitting layer contains an organic light-emitting material. The inorganic light-emitting display panel may be a display panel in which a light-emitting layer contains quantum dots, quantum rods, or micro LEDs. Hereinafter, an organic light-emitting display panel is described as an embodiment of the display panel DP.

The input sensing unit ISU may be disposed on the display panel DP. The input sensing unit ISU may sense an external input applied from the outside. The external input may include various types of inputs provided from the outside of the display device DD (see FIG. 1). The external input may be provided in various forms. For example, the external input may include not only a touch by a part of a body such as a user's hand, but also an external input (e.g., hovering) applied at a place close to or at an adjacent distance from the display device DD (see FIG. 1). The external input may have various forms such as force, pressure, and light, but the disclosure is not limited thereto.

The input sensing unit ISU may be formed on the display panel DP through a continuous process. The input sensing unit ISU may be disposed on (e.g., directly on) the display panel DP. In the specification, the expression “Component B is disposed directly on component A” may mean that a third component is not disposed between component A and component B. For example, an adhesive layer may not be disposed between the input sensing unit ISU and the display panel DP.

The display panel DP may include a base layer BL, a circuit layer DP-CL disposed on the base layer BL, a light-emitting element layer DP-OLED, and an upper insulating layer TFL.

The base layer BL may provide a base surface on which the circuit layer DP-CL, the light-emitting element layer DP-OLED, and the upper insulating layer TFL are disposed. The base layer BL may be a rigid substrate or a flexible substrate capable of being bent, folded, or rolled. The base layer BL may be a glass substrate, a metal substrate, or a polymer substrate. However, the disclosure is not limited thereto, and the base layer BL may include an inorganic layer, an organic layer, or a composite material layer.

The base layer BL may have a multi-layered structure. For example, the base layer BL may include a first synthetic resin layer, a multi-layered or single-layered inorganic layer, and a second synthetic resin layer disposed on the multi-layered or single-layered inorganic layer. Each of the first and second synthetic resin layers may contain a polyimide-based resin, but the disclosure is not particularly limited thereto.

The circuit layer DP-CL may be disposed on the base layer BL. The circuit layer DP-CL may include multiple insulating layers, multiple conductive layers, and a semiconductor layer. The conductive layers of the circuit layer DP-CL may constitute signal lines or control circuits of pixels.

The light-emitting element layer DP-OLED may be disposed on the circuit layer DP-CL. The light-emitting element layer DP-OLED may include a light-emitting element. The light-emitting element layer DP-OLED may include, for example, an organic light-emitting element, an inorganic light-emitting element, an organic-inorganic light-emitting element, a micro LED element, a nano LED element, a quantum dot light-emitting element, an electrophoretic element, an electrowetting element, or the like.

The upper insulating layer TFL may include a capping layer and a thin film encapsulation layer which will be described below. The upper insulating layer TFL may include an organic layer and multiple inorganic layers configured to seal the organic layer.

The upper insulating layer TFL may be disposed on the light-emitting element layer DP-OLED and protect the light-emitting element layer DP-OLED from moisture, oxygen, and foreign substances such as dust particles. The upper insulating layer TFL may seal the light-emitting element layer DP-OLED and block moisture and oxygen from entering to the light-emitting element layer DP-OLED. The upper insulating layer TFL may include at least one inorganic layer. The upper insulating layer TFL may include an organic layer and multiple inorganic layers configured to seal the organic layer. The upper insulating layer TFL may include a structure stacked in the order of an inorganic layer, an organic layer, and another inorganic layer.

The input sensing unit ISU may be disposed on the upper insulating layer TFL. The input sensing unit ISU may be formed on the upper insulating layer TFL through a continuous process. The input sensing unit ISU may be disposed on (e.g., directly on) the display panel DP. For example, a separate adhesive member may not be disposed between the input sensing unit ISU and the display panel DP. The input sensing unit ISU may be disposed to contact an inorganic layer disposed on the uppermost side of the upper insulating layer TFL.

Although not separately illustrated, the display module DM according to an embodiment of the disclosure may further include a protective member disposed on the lower surface of the display panel DP or an anti-reflection member disposed on the upper surface of the input sensing unit ISU. The anti-reflection member may reduce the reflectance of external light. The anti-reflection member may be disposed on (e.g., directly on) the input sensing unit ISU through a continuous process.

The anti-reflection member may include a light blocking pattern overlapping a reflective structure disposed below the anti-reflection member. The anti-reflection member may further include a color filter. The color filter may be disposed between light blocking patterns and include a first color filter, a second color filter, and a third color filter respectively corresponding to a first color pixel, a second color pixel, and a third color pixel.

As illustrated in FIG. 3, the display panel DP may be divided into a display region DP-DA and a non-display region DP-NDA. The display region DP-DA of the display panel DP may be a region in which an image IM (see FIG. 1) is displayed, and the non-display region DP-NDA may be a region in which a driving circuit, a driving line, or the like is disposed. The light-emitting elements of each of pixels may be disposed in the display region DP-DA. The display region DP-DA may overlap at least a portion of the transmission region of the window WM (see FIG. 2) in a plan view, and the non-display region DP-NDA may be covered by the bezel region of the window WM. The display region DP-DA and the non-display region DP-NDA of the display panel DP may respectively correspond to the display region DA and the non-display region NDA of the display device DD illustrated in FIG. 1.

Referring to FIG. 4, the circuit layer DP-CL may include at least one insulating layer and at least one circuit element. The circuit element may include a signal line, a pixel driving circuit, and the like. The circuit layer DP-CL may be formed through a process of forming an insulating layer, a semiconductor layer, and a conductive layer by coating, deposition, or the like and a process of patterning the insulating layer, the semiconductor layer, and the conductive layer through a photolithography process.

A buffer layer BFL may include at least one inorganic layer. A semiconductor pattern may be disposed on the buffer layer BFL. The buffer layer BFL may improve bonding strength between the base layer BL and the semiconductor pattern.

The semiconductor pattern may contain polysilicon. However, the disclosure is not limited thereto, and the semiconductor pattern may contain amorphous silicon or a metal oxide. FIG. 4 illustrates only a portion of the semiconductor pattern, and the semiconductor pattern may be further disposed in another region of a pixel. The semiconductor pattern may be arranged in a pattern across the pixels.

The semiconductor pattern may have an electrical property depending on whether it is doped or not. The semiconductor pattern may include a first region A1 having low doping concentration and low conductivity and second regions S1 and D1 having relatively high doping concentration and relatively high conductivity. One of the second region S1 may be disposed on a side of the first region A1, and another one of the second region D1 may be disposed on another side of the first region A1. The second regions S1 and D1 may be doped with an n-type dopant or a p-type dopant. A p-type transistor may include a doped region doped with a p-type dopant. The first region A1 may be a non-doped region or may be doped at a lower concentration than the second regions S1 and D1.

The second regions S1 and D1 may substantially serve as electrodes or signal lines. One of the second region S1 may correspond to a source of the transistor TR and another one of the second region D1 may correspond to a drain of the transistor TR. FIG. 4 illustrates a portion of a connection signal line SCL formed from a semiconductor pattern. Although not separately illustrated, the connection signal line SCL may be connected to the drain of the transistor TR.

A first insulating layer 10 may be disposed on the buffer layer BFL. The first insulating layer 10 may overlap multiple pixels disposed in the display region DP-DA in common and cover the semiconductor pattern. The first insulating layer 10 may be an inorganic layer and/or an organic layer and have a single-layered or multi-layered structure. The first insulating layer 10 may contain at least one of aluminum oxide, titanium oxide, silicon oxide, silicon oxynitride, zirconium oxide, and hafnium oxide. Not only the first insulating layer 10 but also the insulation layers of the circuit layer DP-CL described below may be inorganic layers and/or organic layers and have a single-layered or multi-layered structure.

A gate G1 may be disposed on the first insulating layer 10. The gate G1 may be a portion of a metal pattern. The gate G1 may overlap the first region A1 in a plan view. In a process of doping the semiconductor pattern, the gate G1 may function as a mask.

A second insulating layer 20 may be disposed on the first insulating layer 10 and cover the gate G1. The second insulating layer 20 may overlap multiple pixels in common in a plan view. An upper electrode UE may be disposed on the second insulating layer 20. The upper electrode UE may overlap the gate G1 in a plan view. The upper electrode UE may include multiple metal layers. In an embodiment of the disclosure, the upper electrode UE may be omitted.

A third insulating layer 30 may be disposed on the second insulating layer 20 and cover the upper electrode UE. A first connection electrode CNE1 may be disposed on the third insulating layer 30. The first connection electrode CNE1 may be connected to the connection signal line SCL through a contact hole CNT-1 passing through the first to third insulating layers 10 to 30.

A fourth insulating layer 40 may be disposed on the third insulating layer 30, and a fifth insulating layer 50 may be disposed on the fourth insulating layer 40. The fourth insulating layer 40 may be an organic layer. A second connection electrode CNE2 may be disposed on the fourth insulating layer 40. The second connection electrode CNE2 may be connected to the first connection electrode CNE1 through a contact hole CNT-2 passing through the fourth insulating layer 40.

The fifth insulating layer 50 may be disposed on the fourth insulating layer 40 and cover the second connection electrode CNE2. The fifth insulating layer 50 may be an organic layer.

A light-emitting element OLED may be disposed on the fifth insulating layer 50. A first electrode AE may be disposed on the fifth insulating layer 50. The first electrode AE may be connected to the second connection electrode CNE2 through a contact hole CNT-3 passing through the fifth insulating layer 50. A pixel opening OP may be defined in a pixel defining film PDL, and the pixel defining film PDL may expose at least a portion of the first electrode AE. The pixel defining film PDL may be an organic layer.

The display region DP-DA may include a pixel region PXA and a non-pixel region NPXA adjacent to the pixel region PXA. The non-pixel region NPXA may surround the pixel region PXA in a plan view. In an embodiment, the pixel region PXA may correspond to a portion of the first electrode AE exposed by the pixel opening OP.

The light-emitting element OLED may include a first electrode AE, a hole transport region HTR, a light-emitting layer EML, an electron transport region ETR, and a second electrode CE. The hole transport region HTR may be disposed on the first electrode AE. The light-emitting layer EML may be disposed on the hole transport region HTR. The second electrode CE may be disposed above the hole transport region HTR. The second electrode CE may have an integral shape.

The hole transport region HTR, the light-emitting layer EML, and the electron transport region ETR may be commonly formed in multiple pixels by using an open mask. However, the disclosure is not limited thereto, and at least one of the hole transport region HTR, the light-emitting layer EML, and the electron transport region ETR may be formed by patterning a layer by a mask.

An upper insulating layer TFL may be disposed on the light-emitting element layer DP-OLED and include multiple thin films. According to an embodiment of the disclosure, the upper insulating layer TFL may include a capping layer CPL and an encapsulation layer TFE disposed on the capping layer CPL. The capping layer CPL may be disposed on and contact the second electrode CE. The capping layer CPL may contain an organic material.

The encapsulation layer TFE may include a first inorganic encapsulation layer TIOL1, an organic encapsulation layer TOL disposed on the first inorganic encapsulation layer TIOL1, and a second inorganic encapsulation layer TIOL2 disposed on the organic encapsulation layer TOL. The first inorganic encapsulation layer TIOL1 and the second inorganic encapsulation layer TIOL2 may protect the light-emitting element layer DP-OLED from moisture or oxygen, and the organic encapsulation layer TOL may protect the light-emitting element layer DP-OLED from foreign substances such as dust particles.

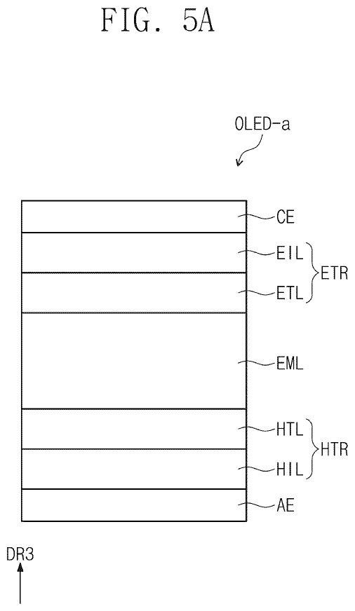

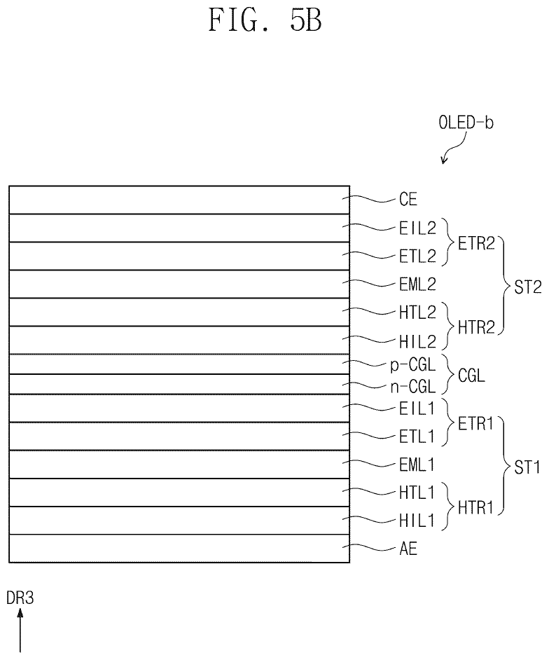

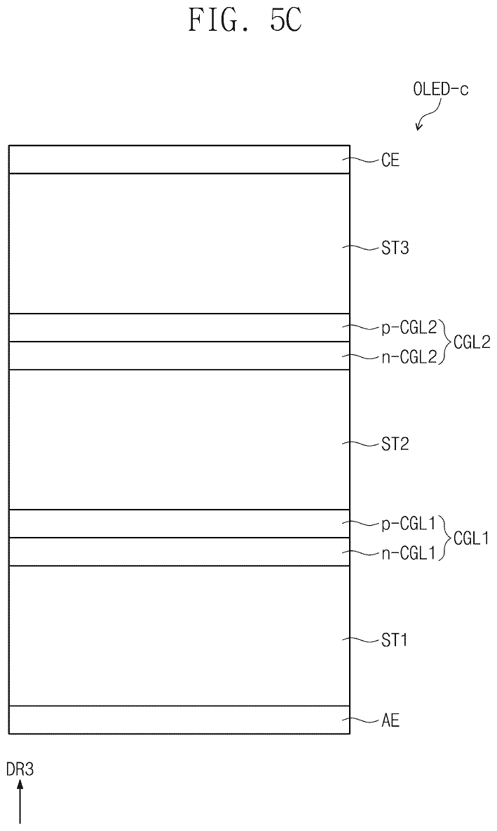

FIGS. 5A to 5C are each a schematic cross-sectional view of a light-emitting element OLED according to an embodiment of the disclosure. FIGS. 5A to 5C each schematically illustrates the light-emitting element OLED according to an embodiment.

Referring to FIG. 5A, a light-emitting element OLED-a according to an embodiment of the disclosure may include a first electrode AE, a hole transport region HTR, a light-emitting layer EML, an electron transport region ETR, and a second electrode CE. The hole transport region HTR of the light-emitting element OLED-a according to an embodiment of the disclosure may include a hole injection layer HIL and a hole transport layer HTL, and the electron transport region ETR may include an electron injection layer EIL and an electron transport layer ETL.

Referring to FIG. 5B, a light-emitting element OLED-b according to an embodiment of the disclosure may include a first electrode AE, a first light-emitting stack ST1, a charge generation layer CGL, a second light-emitting stack ST2, and a second electrode CE. The light-emitting element OLED-b may have a tandem structure including multiple light-emitting stacks ST1 and ST2 including light-emitting layers EML1 and EML2.

The first light-emitting stack ST1 may include a first light-emitting layer EML1, a first hole transport region HTR1, and a first electron transport region ETR1 with the first light-emitting layer EML1 interposed between the first hole transport region HTR1 and the first electron transport region ETR1. The first hole transport region HTR1 may include at least one of a first hole injection layer HIL1 and a first hole transport layer HTL1. The first electron transport region ETR1 may include at least one of a first electron injection layer EIL1 and a first electron transport layer ETL1.

The second light-emitting stack ST2 may include a second light-emitting layer EML2, a second hole transport region HTR2, and a second electron transport region ETR2 with the second light-emitting layer EML2 interposed between the second hole transport region HTR2 and the second electron transport region ETR2. The second hole transport region HTR2 may include at least one of a second hole injection layer HIL2 and a second hole transport layer HTL2. The second electron transport region ETR2 may include at least one of a second electron injection layer EIL2 and a second electron transport layer ETL2.

In an embodiment of the disclosure, light emitted from each of the light-emitting stacks ST1 and ST2 may all have a same wavelength. For example, all of the light emitted from each of the light-emitting stacks ST1 and ST2 may be blue light. However, the disclosure is not limited thereto, and the wavelength ranges of light emitted from the light-emitting stacks ST1 and ST2 may be different from each other. For example, at least one of the light-emitting stacks ST1 and ST2 may emit blue light and another one of the light-emitting stacks ST1 and ST2 may emit green light. The light-emitting element OLED-b including the light-emitting stacks ST1 and ST2 emitting light of different wavelength ranges may emit white light.

The charge generation layer CGL may be disposed between the first light-emitting stack ST1 and the second light-emitting stack ST2. In case that a voltage is applied to the charge generation layer CGL, charges (electrons and holes) may be generated by forming a complex through an oxidation-reduction reaction. The charge generation layer CGL may provide the generated charges to each of the light-emitting stacks ST1 and ST2. The charge generation layer CGL may double the efficiency of current generated in each of the light-emitting stacks ST1 and ST2 and adjust the balance of charges between the first light-emitting stack ST1 and the second light-emitting stack ST2.

The charge generation layer CGL may have a multi-layered structure in which an n-type charge generation layer n-CGL and a p-type charge generation layer p-CGL are stacked with each other. The n-type charge generation layer n-CGL may provide electrons to adjacent stacks. The n-type charge generation layer n-CGL may be a layer in which a base material is doped with an n-type dopant. The p-type charge generation layer p-CGL may provide holes to adjacent stacks. Although not illustrated, a buffer layer may be further disposed between the n-type charge generation layer n-CGL and the p-type charge generation layer p-CGL.

The charge generation layer CGL may contain an n-type arylamine-based material or a p-type metal oxide. For example, the charge generation layer CGL may contain a charge generation compound including an arylamine-based organic compound, a metal, a metal oxide, a metal carbide, a metal fluoride, or a mixture thereof. For example, the arylamine-based organic compound of the charge generation compound may be α-NPD, 2-TNATA, TDATA, MTDATA, sprio-TAD, or sprio-NPB. For example, the metal may be cesium (Cs), molybdenum (Mo), vanadium (V), titanium (Ti), tungsten (W), barium (Ba), or lithium (Li). For example, the metal oxide, the metal carbide, and the metal fluoride of the charge generation compound may be Re₂O₇, MoO₃, V₂O₅, WO₃, TiO₂, Cs₂CO₃, BaF, LiF, or CsF.

According to an embodiment, the first light-emitting stack ST1, the charge generation layer CGL, and the second light-emitting stack ST2 may be commonly formed in multiple pixels by using an open mask. However, the disclosure is not limited thereto, and at least one of the first hole control layer HTR1, the second hole control layer HTR2, the first light-emitting layer EML1, the second light-emitting layer EML2, the first electron control layer ETR1, or the second electron control layer ETR2 may be formed by patterning a layer using a mask.

The second electrode CE may be disposed on the second light-emitting stack ST2. The second electrode CE may have an integral shape and be commonly disposed in multiple pixels.

Referring to FIG. 5C, a light-emitting element OLED-c according to an embodiment of the disclosure may include a first electrode AE, a first light-emitting stack ST1, a first charge generation layer CGL1, a second light-emitting stack ST2, a second charge generation layer CGL2, a third light-emitting stack ST3, and a second electrode CE. For example, the light-emitting element OLED-c may include three light-emitting stacks ST1, ST2, and ST3 and two charge generation layers CGL1 and CGL2 disposed between adjacent light-emitting stacks ST1, ST2, and ST3. Same/similar reference numerals will be used for the same/similar components as those described in FIGS. 5A and 5B, and redundant descriptions will be omitted.

The third light-emitting stack ST3 may have a structure similar to those of the first and second light-emitting stacks ST1 and ST2 described above with reference to FIG. 5B. The third light-emitting stack ST3 may include a third hole transport region, a third light-emitting layer, and a third electron transport region sequentially stacked in the third direction DR3 on the second electron transport region ETR2 (see FIG. 5B).

Each of the first and second charge generation layers CGL1 and CGL2 may have a structure similar to that of the charge generation layer CGL described above with reference to FIG. 5B. The first charge generation layer CGL1 may have a stacked structure in which a first n-type charge generation layer n-CGL1 and a first p-type charge generation layer p-CGL1 are stacked with each other, and the second charge generation layer CGL2 may have a stacked structure in which a second n-type charge generation layer n-CGL2 and a second p-type charge generation layer p-CGL2 are stacked with each other.

The number of light-emitting stacks ST1, ST2, and ST3 and charge generation layers CGL1 and CGL2 is not limited to those illustrated in FIGS. 5B and 5C, and a light-emitting element may include four or more light-emitting stacks and three or more charge generation layers disposed therebetween.

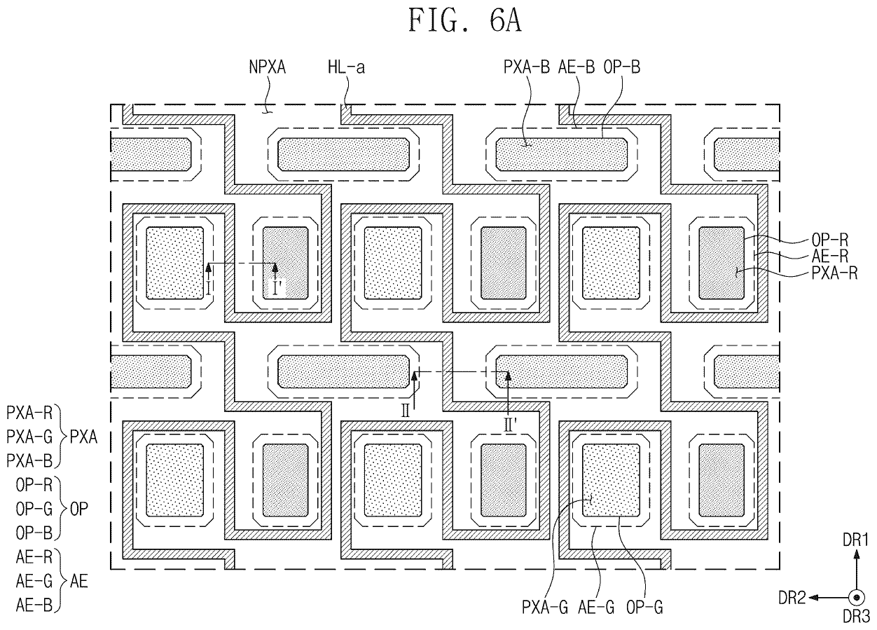

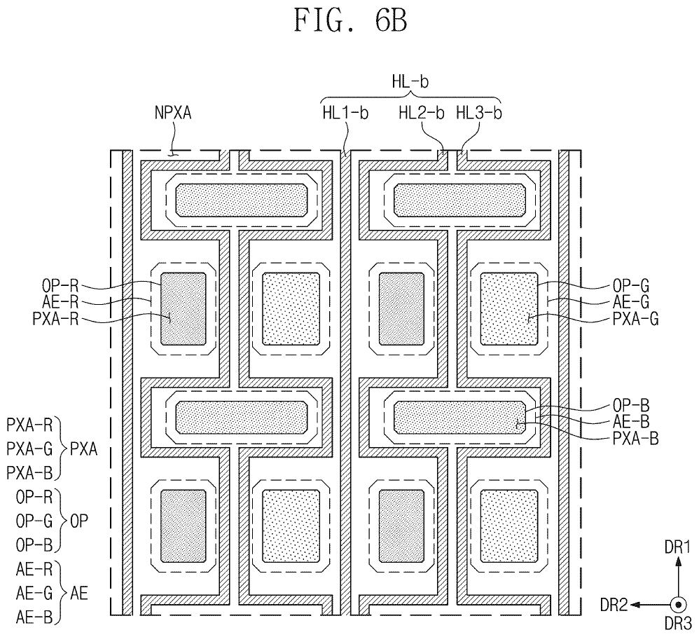

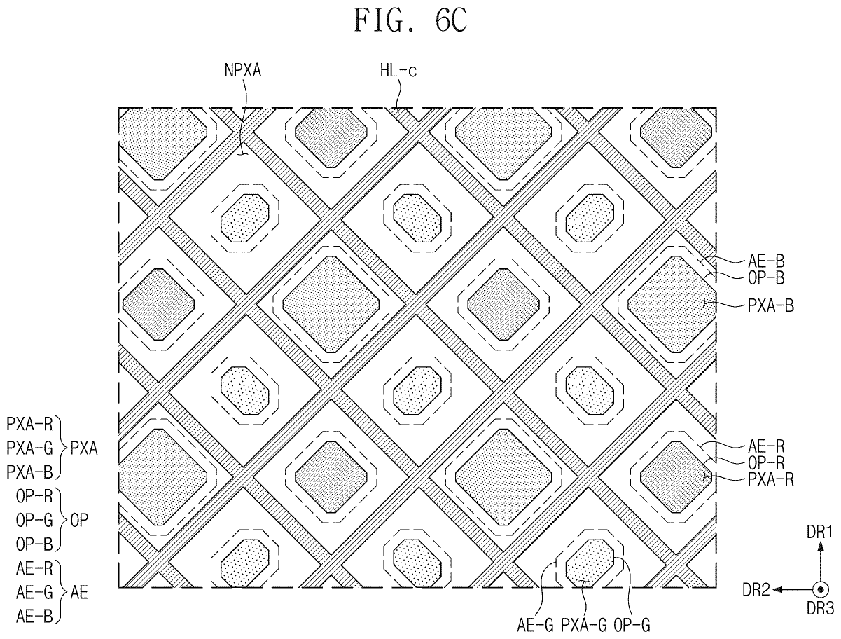

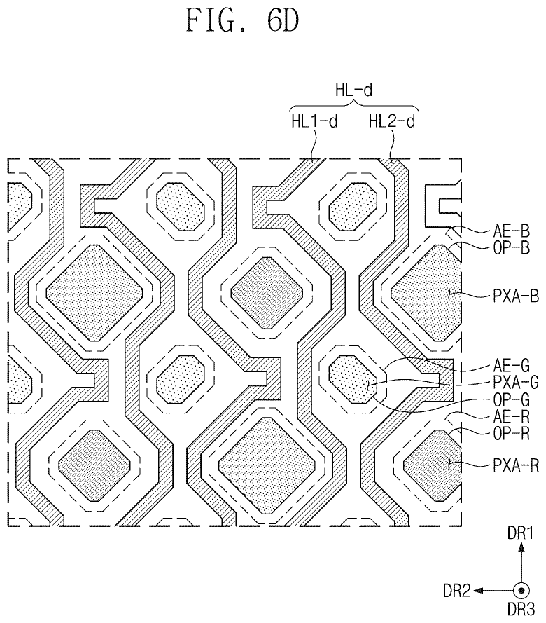

FIGS. 6A to 6D are each a plan view of a portion of the display panel DP according to an embodiment of the disclosure.

Each of FIGS. 6A to 6D is an enlarged view illustrating region AA′ of FIG. 2. The regions FIGS. 6A to 6D illustrate do not correspond to a same area, but each of FIGS. 6A to 6D illustrates a region with different areas to represent each feature more efficiently.

Among the components of the light-emitting element layer DP-OLED, FIGS. 6A to 6D illustrate a first electrode AE, a non-pixel region NPXA formed by disposing the pixel defining film PDL (see FIG. 4) on the first electrode AE, and a pixel region PXA defined by a pixel opening OP, and organic layers (e.g., light-emitting layer EML, see FIG. 4) and a second electrode CE above the first electrode AE are not illustrated. The first electrode AE may be exposed through the pixel opening OP.

Referring to FIGS. 6A to 6D, the display panel DP according to an embodiment of the disclosure may include a pixel region PXA and a non-pixel region NPXA surrounding the pixel region PXA. The pixel region PXA may include multiple pixel regions, and for example, the pixel region PXA may include first to third pixel regions PXA-R, PXA-G, and PXA-B.

Each of the first to third pixel regions PXA-R, PXA-G, and PXA-B may be a region of the upper surface of a corresponding first electrode AE-R, AE-G, or AE-B exposed by a corresponding pixel opening OP-R, OP-G, or OP-G.

Although organic layers such as a light-emitting layer EML (see FIG. 4) are not illustrated in FIGS. 6A to 6D, the first to third pixel regions PXA-R, PXA-G, and PXA-B may be distinguished (or different) from each other according to the color of light emitted by a light-emitting layer EML. For example, the first pixel region PXA-R may emit a first light of a red wavelength range, the second pixel region PXA-G may emit a second light of a green wavelength range, and the third pixel region PXA-B may emit a third light of a blue wavelength range.

The non-pixel region NPXA may set the boundaries of the first to third pixel regions PXA-R, PXA-G, and PXA-B and prevent color mixing between the first to third pixel regions PXA-R, PXA-G, and PXA-B.

As illustrated in FIGS. 6A and 6B, the first to third pixel regions PXA-R, PXA-G, and PXA-B may be arranged in a stripe pattern. In another embodiment, as illustrated in FIGS. 6C and 6D, the first to third pixel regions PXA-R, PXA-G, and PXA-B may be arranged in a PENTILE™ pattern. However, the disclosure is not limited thereto, and the first to third pixel regions PXA-R, PXA-G, and PXA-B may be arranged in various patterns such as Diamond Pixel™.

The display panel DP according to an embodiment may include a heating line. The heating line may be disposed in the non-pixel region NPXA and may surround the pixel regions PXA-R, PXA-G, and PXA-B in a plan view.

The heating line may contain a metal. For example, the heating line may contain at least one of Mo, Ti, TiN, W, Al, indium tin oxide (ITO), indium zinc oxide (IZO), and the like.

Referring to FIGS. 6A to 6D, each of heating lines HL-a, HL-b, HL-c, and HL-d may surround the pixel regions PXA-R, PXA-G, and PXA-B and may extend in the first direction DR1 and in the second direction DR2.

In the following description of FIGS. 6A to 6D, the upper, lower, left, and right sides of the first to third pixel regions PXA-R, PXA-G, and PXA-B are defined as follows. The upper side may be a region of the non-pixel region NPXA in the first direction DR1 adjacent to and surrounding the first to third pixel regions PXA-R, PXA-G, and PXA-B. The lower side may be a region of the non-pixel region NPXA in a direction opposite to the first direction DR1 adjacent to and surrounding the first to third pixel regions PXA-R, PXA-G, and PXA-B. The left side may be a region of the non-pixel region NPXA in the second direction DR2 adjacent to and surrounding the first to third pixel regions PXA-R, PXA-G, and PXA-B. The right side may be a region of the non-pixel region NPXA in a direction opposite to the second direction DR2 adjacent to and surrounding the first to third pixel regions PXA-R, PXA-G, and PXA-B.

Referring to FIG. 6A, in a plan view, a heating line HL-a may extend along a left and lower sides of a third pixel region PXA-B, extend along an upper, right, lower, and left sides of a first pixel region PXA-R disposed below the third pixel region PXA-B in a plan view, and extend along a right, upper, left, and lower sides of a second pixel region PXA-G disposed on the left side of the first pixel region PXA-R in a plan view. The heating line HL-a having the above arrangement may generally extend in the first direction DR1. The heating line HL-a having the above arrangement may be repeatedly arranged to be spaced apart from each other in the second direction DR2.

Referring to FIG. 6B, a heating line HL-b may include first to third heating lines HL1-b, HL2-b, and HL3-b. The first to third heating lines HL1-b, HL2-b, and HL3-b may be electrically connected to each other to form one heating line HL-b. However, the disclosure is not limited thereto, and the first to third heating lines HL1-b, HL2-b, and HL3-b may be separate heating lines that are not electrically connected to each other.

For example, the first heating line HL1-b may extend straight in the first direction DR1. The second heating line HL2-b may extend along an upper, left, and lower sides of a third pixel region PXA-B and extend along a right side of a first pixel region PXA-R disposed below the third pixel region PXA-B. The second heating lines HL2-b having the arrangement may be repeatedly connected to each other in the first direction DR1. The second heating lines HL2-b having the arrangement may be repeatedly arranged to be spaced apart from each other in the second direction DR2. The third heating line HL3-b may extend along an upper, right, and lower sides of a third pixel region PXA-B and extend along a left side of a second pixel region PXA-G disposed below the third pixel region PXA-B in a plan view. The third heating lines HL3-b having the arrangement may be repeatedly connected to each other in the first direction DR1. The third heating lines HL3-b having the arrangement may be repeatedly arranged to be spaced apart from each other in the second direction DR2.

Referring to FIG. 6C, a heating line HL-c may be arranged in a mesh shape in a plan view. For example, the heating line HL-c may have a shape in which one of the first to third pixel regions PXA-R, PXA-G, and PXA-B are arranged in each mesh-shaped hole. The heating line HL-c may have a mesh shape electrically integrally connected.

Referring to FIG. 6D, a heating line HL-d may include a first and a second heating lines HL1-d and HL2-d. The first and second heating lines HL1-d and HL2-d may be electrically connected to each other to form one heating line HL-d. However, the disclosure is not limited thereto, and the first and second heating lines HL1-d and HL2-d may be separate heating lines that are not electrically connected to each other.

For example, the first heating line HL1-d may generally extend in the first direction DR1 along a left side of a second pixel region PXA-G, a right side of a first pixel region PXA-R disposed below the second pixel region PXA-G, a left side of another second pixel region PXA-G disposed below the second pixel region PXA-G, and a right side of a third pixel region PXA-B disposed below the first pixel region PXA-R in a plan view. The second heating line HL2-d may generally extend in the first direction DR1 along a right side of a second pixel region PXA-G, a left side of a third pixel region PXA-B disposed below the second pixel region PXA-G, a right side of another second pixel region PXA-G disposed below the second pixel region PXA-G, and a left side of a first pixel region PXA-R disposed below the third pixel region PXA-B in a plan view. The first heating line HL1-d and the second heating line HL2-d may be repeatedly and alternatively arranged to be spaced apart from each other in the second direction DR2.

However, the arrangement forms of the heating lines according to this disclosure are not limited to the arrangement forms illustrated in FIGS. 6A to 6D as long as the heating lines surround the pixel region PXA.

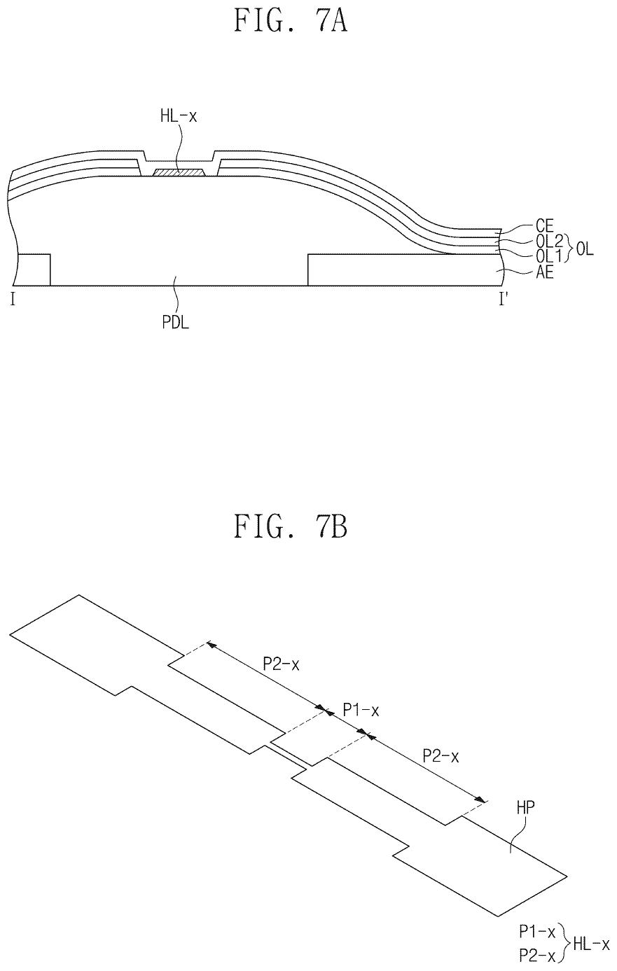

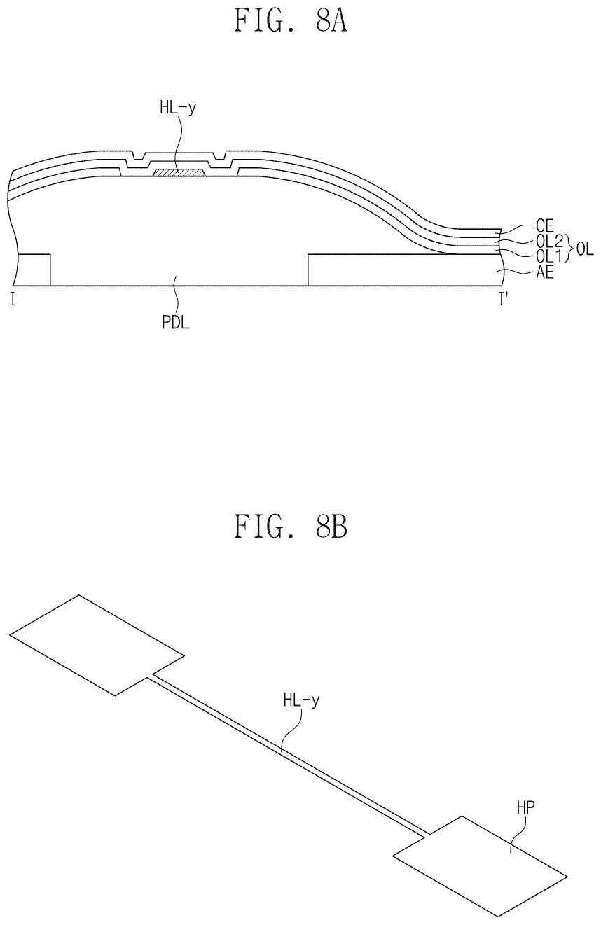

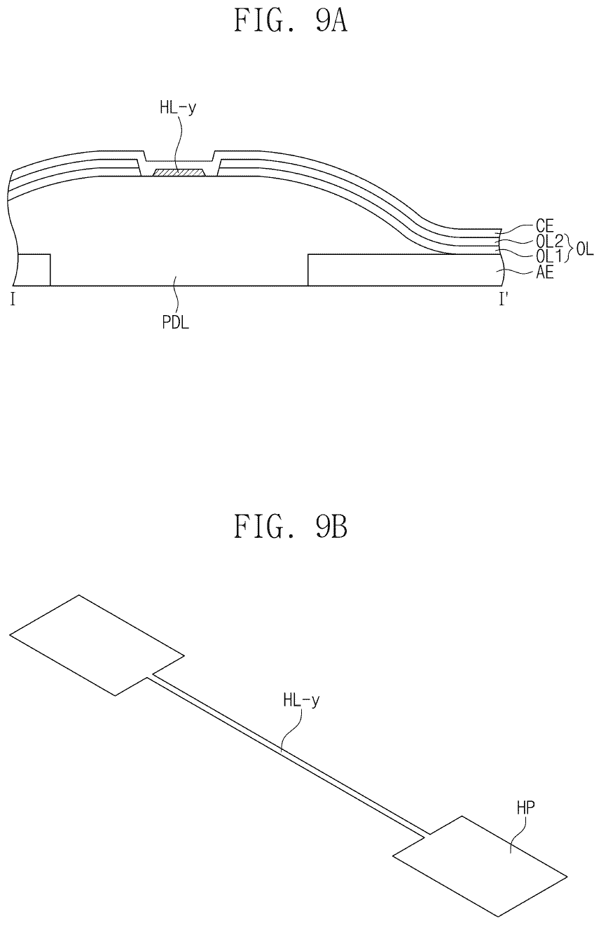

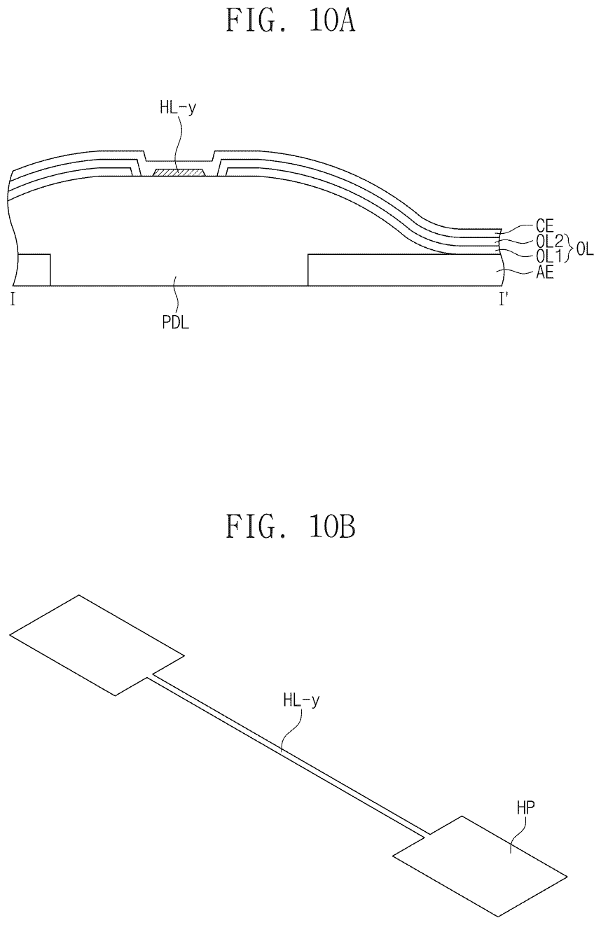

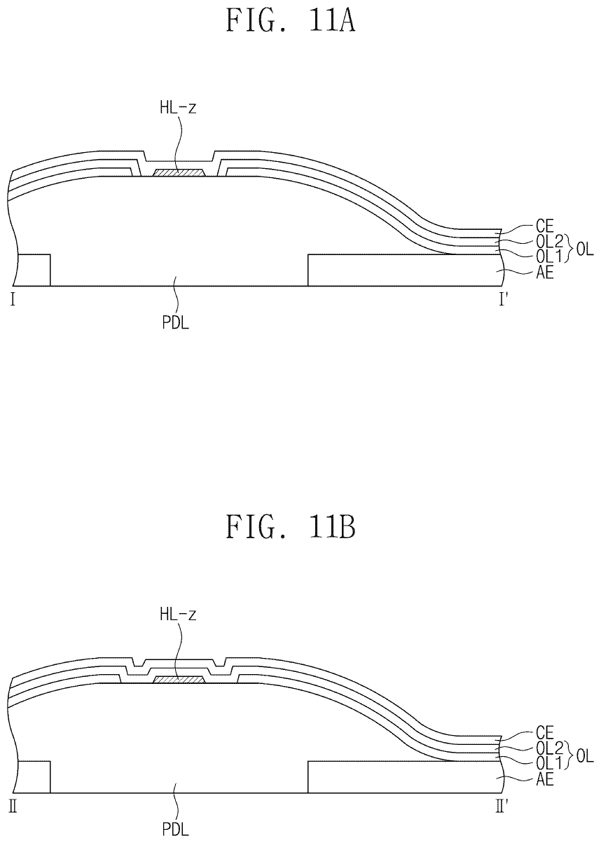

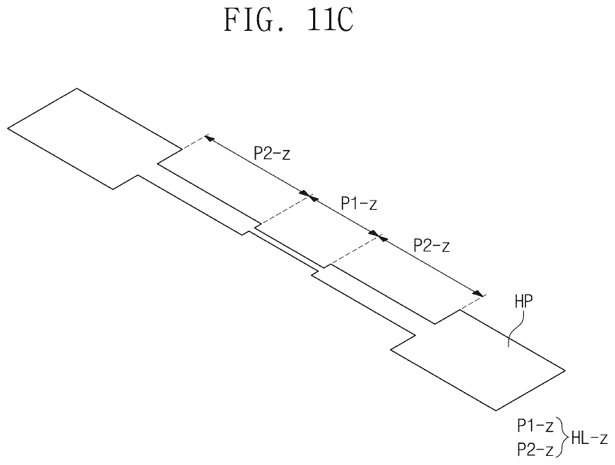

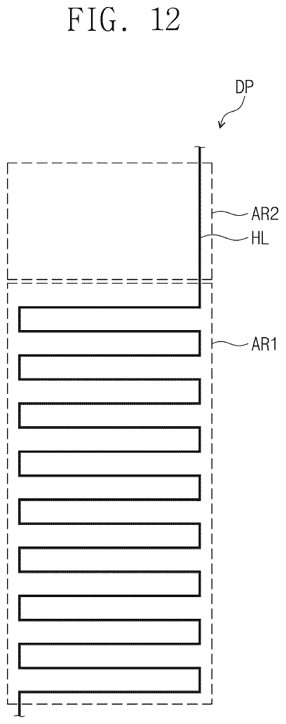

FIG. 7A is a schematic cross-sectional view of a portion of the display panel according to an embodiment of the disclosure. FIG. 7B is a perspective view schematically illustrating a heating line HL-x and a heating pad HP according to an embodiment of the disclosure. FIG. 8A is a schematic cross-sectional view of a portion of the display panel according to an embodiment of the disclosure. FIG. 8B is a perspective view schematically illustrating a heating line HL-y and a heating pad HP according to an embodiment of the disclosure. FIG. 9A is a schematic cross-sectional view of a portion of the display panel according to an embodiment of the disclosure. FIG. 9B is a perspective view schematically illustrating a heating line HL-y and a heating pad HP according to an embodiment of the disclosure. FIG. 10A is a schematic cross-sectional view of a portion of the display panel according to an embodiment of the disclosure. FIG. 10B is a perspective view schematically illustrating a heating line HL-y and a heating pad HP according to an embodiment of the disclosure. FIGS. 11A and 11B area each a schematic cross-sectional view of a portion of the display panel according to an embodiment of the disclosure. FIG. 11C is a perspective view schematically illustrating a heating line HL-z and a heating pad HP according to an embodiment of the disclosure. FIG. 12 is a plan view of a portion of the display panel DP according to an embodiment of the disclosure. With respect to FIGS. 7A to 12, the descriptions of components overlapping those described above are omitted.

FIGS. 7A, 8A, 9A, 10A, and 11A schematically illustrate cross-sections corresponding to line I-I′ of FIG. 6A. FIG. 11B schematically illustrates a cross section corresponding to line II-II′ of FIG. 6A.

FIG. 7A schematically illustrates a cross section corresponding to line I-I′ of FIG. 6A, and FIG. 7B schematically illustrates a spread out heating line HL-x of FIG. 7A.

Referring to FIG. 7B, the heating line HL-x may include a first portion P1-x and a second portion P2-x having a greater width than the first portion P1-x in a lateral direction of the heating line. Since the second portion P2-x has a greater width, in case that a same voltage is applied, the first portion P1-x may have a higher temperature than the second portion P2-x, and therefore, only an organic layer OL adjacent to the first portion P1-x may be removed. For example, a portion of the organic layer OL disposed less than or equal to about 5 μm from the center of the heating line HL-x may be removed. For example, a portion of the organic layer OL disposed less than or equal to about 4 μm from the center of the heating line HL-x may be removed. For example, a portion of the organic layer OL disposed less than or equal to about 3 μm from the center of the heating line HL-x may be removed. For example, a portion of the organic layer OL disposed less than or equal to about 0.5 μm from the center of the heating line HL-x may be removed. The center of the heating line HL-x may be defined with respect to a lateral direction of the heating line HL-x.

Referring to FIG. 7A, an organic layer OL may be formed as a common layer, a voltage may be applied to the heating line HL-x to remove the organic layer OL adjacent to the first portion P1-x, and a second electrode CE may be formed as a common layer. A detailed description of the manufacturing method will be provided below.

FIG. 7A may be a cross-section of a position corresponding to the first portion P1-x of FIG. 7B. For example, the organic layer OL adjacent to the first portion P1-x may be removed, and the heating line HL-x may be electrically connected to the second electrode CE. On the other hand, an organic layer OL adjacent to the second portion P2-x may not be removed, and the organic layer OL may be disposed to cover the heating line HL-x.

Although FIG. 7B illustrates that the heating line HL-x includes one first portion P1-x, the disclosure is not limited thereto, and the heating line HL-x may include multiple first portions P1-x at which the organic layer OL is removed and the heating line HL-x and the second electrode CE are electrically connected to each other. Although FIG. 7B illustrates that the heating line HL-x has two widths, the disclosure is not limited thereto, and the heating line HL-x may include three or more widths.

For example, the heating line HL-x which may include different widths may be disposed on the pixel defining film PDL. Only the organic layer OL adjacent to the heating line HL-x corresponding to the first portion P1-x having a small width may be removed. The heating line HL-x and the second electrode CE may be electrically connected to each other to prevent a voltage drop. In case that the first portion P1-x having a small width is disposed between pixel regions, a lateral leakage current may be prevented, and thus, color mixing between adjacent pixel regions may be prevented.

FIG. 8A schematically illustrates a cross section corresponding to line I-I′ of FIG. 6A, and FIG. 8B schematically illustrates a spread out heating line HL-y of FIG. 8A.

Referring to FIG. 8B, the heating line HL-y may have one width.

Referring to FIG. 8A, a first organic layer OL1 may be formed as a common layer, a voltage may be applied to the heating line HL-y to remove the first organic layer OL1 adjacent to the heating line HL-y, and a second organic layer OL2 and a second electrode CE may be formed as a common layer. A detailed description of the manufacturing method will be provided below.

Referring to FIG. 8A, the first organic layer OL1 adjacent to the heating line HL-y may be removed, and the heating line HL-y may be covered by the second organic layer OL2.

For example, the heating line HL-y having a width may be disposed on the pixel defining film PDL. A lateral leakage current may be prevented by removing the first organic layer OL1 adjacent to the heating line HL-y, and thus, color mixing between adjacent pixel regions may be prevented.

FIG. 9A schematically illustrates a cross section corresponding to line I-I′ of FIG. 6A, and FIG. 9B schematically illustrates a spread out heating line HL-y of FIG. 9A.

Referring to FIG. 9B, the heating line HL-y may have one width.

Referring to FIG. 9A, the organic layer OL may be formed as a common layer, a voltage may be applied to the heating line HL-y to remove the organic layer OL adjacent to the heating line HL-y, and the second electrode CE may be formed as a common layer. A detailed description of the manufacturing method will be provided below.

Referring to FIG. 9A, the organic layer OL adjacent to the heating line HL-y may be removed, and the heating line HL-y may contact and be electrically connected to the second electrode CE.

In the embodiment of FIG. 7B, since the heating line HL-x includes different widths, only the organic layer OL adjacent to the first portion P1-x may be removed, but since the heating line HL-y of FIG. 9B has one width, the organic layer OL adjacent to the entire region of the heating line HL-y may be removed.

For example, the heating line HL-y having a width may be disposed on the pixel defining film PDL. The heating line HL-y and the second electrode CE may be electrically connected to each other to prevent a voltage drop. Since the organic layer OL adjacent to the heating line HL-y is removed, a lateral leakage current may be prevented, and thus, color mixing between adjacent pixel regions may be prevented.

FIG. 10A schematically illustrates a cross section corresponding to line I-I′ of FIG. 6A, and FIG. 10B schematically illustrates a spread out heating line HL-y of FIG. 10A.

Referring to FIG. 10B, the heating line HL-y may have one width.

Referring to FIG. 10A, a first organic layer OL1 may be formed as a common layer, a first pulse voltage may be applied to the heating line HL-y to remove the first organic layer OL1 adjacent to the heating line HL-y, a second organic layer OL2 may be formed as a common layer, a second pulse voltage may be applied to the heating line HL-y to remove the second organic layer OL2 adjacent to the heating line HL-y, and the second electrode CE may be formed as a common layer. The pulse width of the first pulse voltage may be greater than the pulse width of the second pulse voltage, and the removal range of the first organic layer OL1 removed by applying the first pulse voltage may be wider than the removal range of the second organic layer OL2 removed by applying the second pulse voltage. A detailed description of the manufacturing method will be provided below.

Referring to FIG. 10A, the organic layer OL adjacent to the heating line HL-y may be removed, and the heating line HL-y may contact and be electrically connected to the second electrode CE.

In the embodiment of FIG. 9A, since the voltage is applied to the heating line HL-y after both the first and second organic layers OL1 and OL2 are formed, the removal ranges of the first and second organic layers OL1 and OL2 may be substantially similar to each other. On the other hand, in the embodiment of FIG. 10A, after each step of forming the first organic layer OL1 and forming the second organic layer OL2, the first pulse voltage and the second pulse voltage having pulse widths different from each other are applied to the heating line HL-y in each step, and therefore, the removal ranges of the first and second organic layers OL1 and OL2 may be different from each other. The first organic layer OL1 and the second organic layer OL2 are not limited to a layer, and the embodiment may be applied to any layer that different portions need to be removed.

For example, the heating line HL-y having a width may be disposed on the pixel defining film PDL. The heating line HL-y and the second electrode CE may be electrically connected to each other to prevent a voltage drop. Since the organic layer OL adjacent to the heating line HL-y is removed, a lateral leakage current may be prevented, and thus, color mixing between adjacent pixel regions may be prevented. Since the first and second pulse voltages having pulse widths different from each other may be applied to one heating line HL-y in different steps, the removal ranges of the first and second organic layers OL1 and OL2 may be different from each other.

FIG. 11A schematically illustrates a cross section corresponding to line I-I′ of FIG. 6A, and FIG. 11B schematically illustrates a cross section corresponding to line II-II′ of FIG. 6A. The position of line II-II′ in FIG. 6A is not limited and is different from the position of line I-I′. FIG. 11C schematically illustrates spread out heating line HL-z of FIGS. 11A and 11B.

Referring to FIG. 11C, the heating line HL-z may include a first portion P1-z and a second portion P2-z having a width greater than a width of the first portion P1-z. Since the second portion P2-z has a greater width, in case that a same voltage is applied, the temperature of the first portion P1-x may be higher than the temperature of the second portion P2-x.

Referring to FIGS. 11A and 11B, a first organic layer OL1 may be formed as a common layer, a first pulse voltage may be applied to the heating line HL-z to remove the first organic layer OL1 adjacent to the first and second portions P1-z and P2-z (see FIG. 11C), a second organic layer OL2 may be formed as a common layer, a second pulse voltage may be applied to the heating line HL-z to remove only the second organic layer OL2 adjacent to the first portion P1-z, and a second electrode CE may be formed as a common layer. The voltage of the first pulse voltage may be higher than the voltage of the second pulse voltage. A detailed description of the manufacturing method will be provided below.

FIG. 11A may be a cross section of a position corresponding to the first portion P1-z of FIG. 11C. For example, the first and second organic layers OL1 and OL2 adjacent to the first portion P1-z may be removed, and the heating line HL-z may be electrically connected to the second electrode CE.

FIG. 11B may be a cross-section of a position corresponding to the second portion P2-z of FIG. 11C. For example, the first organic layer OL1 adjacent to the second portion P2-z may be removed, but the second organic layer OL2 is not removed so that the second organic layer OL2 may be disposed to cover the heating line HL-z.

Although FIG. 11C illustrates that the heating line HL-z includes one first portion P1-z, the disclosure is not limited thereto, and in case that multiple positions of the first and second organic layers OL1 and OL2 need to be removed, the heating line HL-z may include multiple first portions P1-x. Although FIG. 11C illustrates that the heating line HL-z include two second portions P2-z, in case that only the first organic layer OL1 is removed and there are three or more positions at which the second organic layer OL2 needs to be maintained, the heating line HL-z may include three or more second portions P2-z.

For example, the heating line HL-z having different widths may be disposed on the pixel defining film PDL, and first and second pulse voltages having pulse widths different from each other may be applied to one heating line HL-z in different steps, and therefore, the removal ranges of the first and second organic layers OL1 and OL2 may be different from each other in a plan view. In a portion adjacent to the first portion P1-z, all of the first and second organic layers OL1 and OL2 may be removed and therefore, the heating line HL-z and the second electrode CE may be electrically connected to each other, thus preventing a voltage drop. Since the first organic layer OL1 is removed in a portion adjacent to the second portion P2-z, a lateral leakage current may be prevented, and therefore, color mixing between adjacent pixel regions may be prevented.

In FIGS. 7B, 8B, 9B, 10B, and 11C, a heating pad HP may be connected to a power source for applying a pulse voltage to the heating lines HL-x, HL-y, and HL-z. The heating pad HP may be disposed outside the display panel during a manufacturing process of the display panel, and the heating pad HP may be removed after a process of removing an organic layer OL.

FIG. 12 is an enlarged plan view of a portion of the display panel DP according to an embodiment of the disclosure. FIGS. 7A to 11C describe a structure in which the organic layer OL of a local region adjacent to the heating lines HL-x, HL-y, and HL-z is removed, and FIG. 12 schematically illustrates the arrangement of the heating line HL for removing an organic layer OL having a large region.

Referring to FIG. 12, the heating line HL may be disposed in a first region AR1 at a high density and in a second region AR2 at a low density.

In the heating line HL having a width, in case that a pulse voltage is applied, only the organic layer corresponding to the first region AR1 disposed at a high density may be removed. The heating line HL corresponding to the first region AR1 may contact and be electrically connected to the second electrode, and thus, a voltage drop may be prevented.

In summary, the width of the heating line, the width of the applied pulse voltage, the magnitude of the applied pulse voltage, and/or the step of applying the pulse voltage may be adjusted. Accordingly, an organic layer to be removed may be selected, and a position and a removal range with respect to removal of the organic layer may be selected.

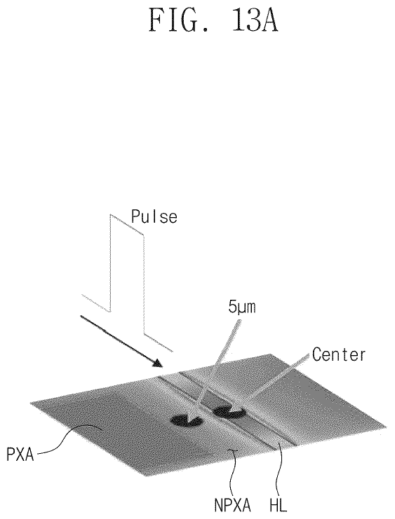

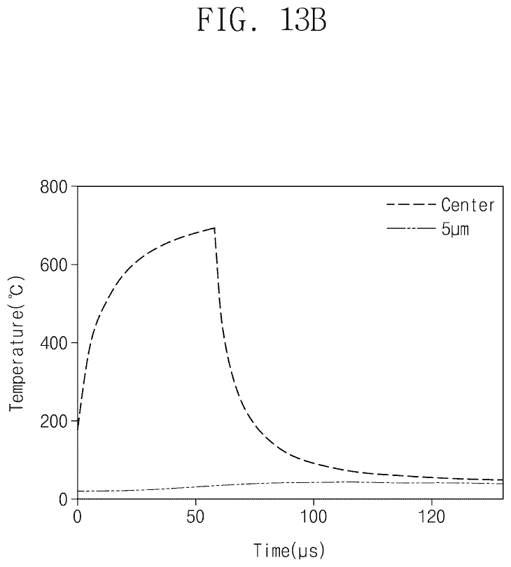

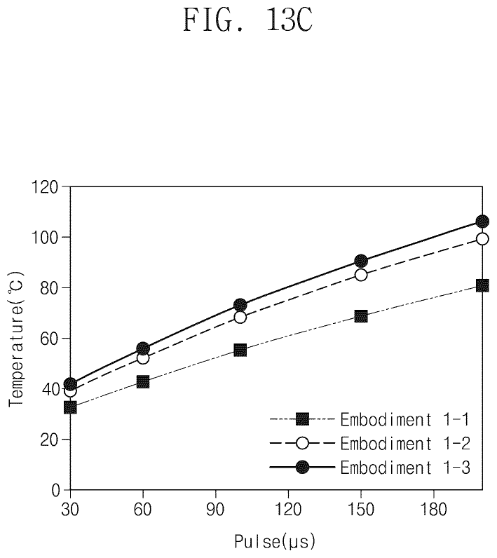

FIG. 13A is a perspective view schematically illustrating a portion of the display panel according to an embodiment of the disclosure. FIG. 13B is a graph obtained by measuring the temperatures of a heating line and a peripheral portion according to an embodiment of the disclosure. FIG. 13C is a graph obtained by measuring the temperatures of a peripheral portion of the heating line according to an embodiment of the disclosure.

FIG. 13A schematically illustrates a step of heating the heating line HL disposed in the non-pixel region NPXA by applying a pulse voltage to the heating line HL.

FIG. 13B is a graph obtained by measuring the temperatures at the center of the heating line HL illustrated in FIG. 13A and the temperatures at a position of about 5 μm from the center of the heating line HL over time by simulation when a pulse voltage having a width of about 60 μm is applied to the heating line HL. Here, the width of the heating line HL is about 2.5 μm, and Mo is used as a material of the heating line HL.

Referring to FIGS. 13A and 13B together, since the temperature at the center of the heating line HL rises to about 700° C., the organic layer adjacent to the heating line HL may be removed. On the other hand, since a temperature of less than about 100° C. is maintained at a position of about 5 μm from the center of the heating line HL, the organic material may be maintained without being damaged in a region in which the organic layer should be maintained, for example, in the pixel region PXA.

FIGS. 13A and 13B evaluate whether or not the organic layer is damaged at a position of about 5 μm from the center of the heating line HL when the width of the heating line HL is about 2.5 μm and a pulse voltage having a width of about 60 μm is applied, and the width of the heating line HL and the applied pulse voltage are not limited thereto and may vary depending on the range in which the organic layer needs to be removed.

FIG. 13C is a graph obtained by measuring the temperatures of the heating lines HL with different widths by simulation at a position of about 5 μm from the center of the heating line HL according to an applied pulse voltage. Here, Mo was used as a material of the heating line HL, and the widths of the heating lines of Embodiment 1-1, Embodiment 1-2, and Embodiment 1-3 were respectively measured to be about 2.5 μm, about 5.0 μm, and about 7.5 μm. The widths were measured while the temperature at the center of the heating lines HL was about 700° C.

Referring to FIG. 13C, in case that a pulse voltage having a pulse width of about 180 μm or less is applied, a temperature of less than about 100° C. is maintained at a position of about 5 μm from the center of the heating line HL, and therefore, the organic material may be maintained without being damaged in a region in which the organic layer need be maintained, for example, in the pixel region.

FIG. 13C evaluates whether or not the organic layer is damaged at a position of about 5 μm from the center of the heating line HL in case that the width of the heating line is about 2.5 μm, about 5.0 μm, and about 7.5 μm, but the width of the heating line and the applied pulse voltage are not limited thereto and may vary according to the range in which the organic layer needs to be removed.

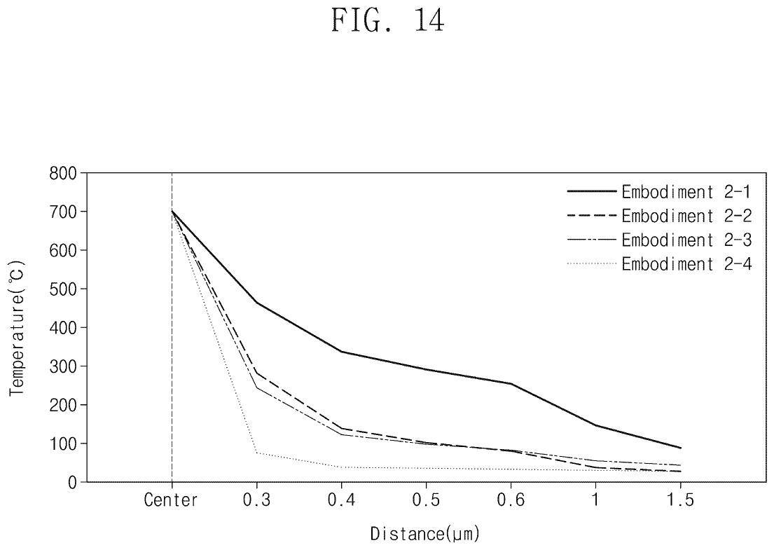

FIG. 14 is a graph obtained by measuring the temperatures of a heating line and a peripheral portion according to an embodiment of the disclosure.

FIG. 14 is a graph obtained by measuring the temperatures of a substrate by simulation according to a separation distance from the center of a heating line, in case that the width of the heating line is about 0.2 μm, in order to apply to micro LED. For example, in the case of the micro LED, the distance between the pixel defining films PDL (see FIG. 4), for example, the width of the pixel opening OP (see FIG. 4) may be in a range of about 1 μm to about 2 μm, and the width of the pixel defining film PDL (see FIG. 4) may be about 1 μm. A silicon (Si) substrate may be applied to the micro LED as a base layer BL (see FIG. 4).

Mo was used as a material for the heating lines of Embodiments 2-1 to 2-4, the thickness of the substrate was about 0.25 μm, and the thickness of the substrate was measured while the temperature at the center of the heating line was about 700° C. A glass substrate was used in Embodiments 2-1 and 2-2, and a silicon (Si) substrate was used in Embodiments 2-3 and 2-4. In Embodiments 2-1 and 2-3, a pulse voltage of about 10 μm was applied, and in Embodiments 2-2 and 2-4, a pulse voltage of about 1 μm was applied.

Referring to FIG. 14, in case that a heating line having a width of about 0.2 μm is applied to the silicon substrate, a temperature of less than 100° C. is maintained at a position of about 0.5 μm or more from the center of the heating line. Therefore, in a region in which the organic layer needs to be maintained, for example, in the pixel region, the organic material may be maintained without being damaged. For example, the heating line according to the disclosure may be applied to the micro LED as well.

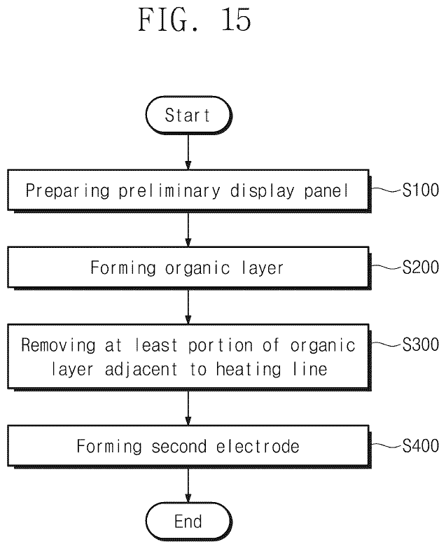

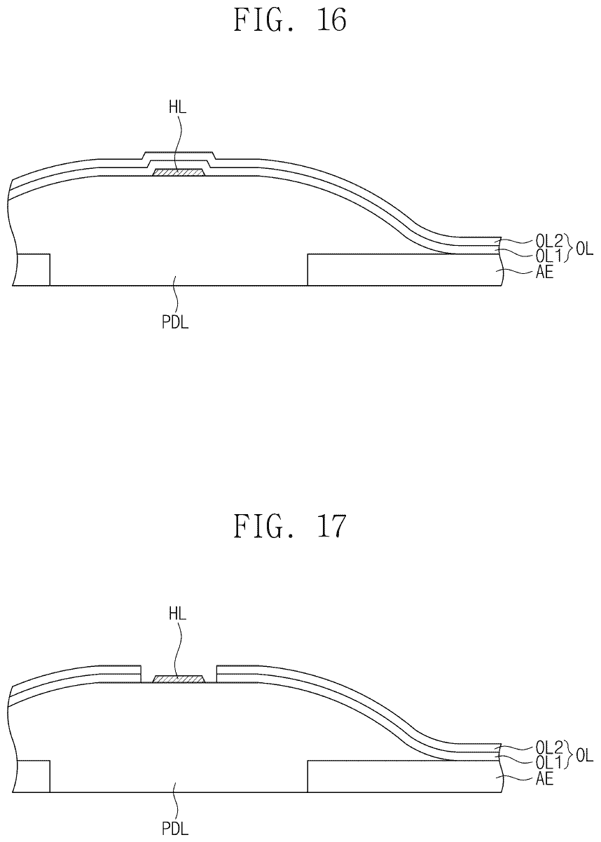

FIG. 15 is a flowchart of a method of manufacturing the display panel according to an embodiment of the disclosure. FIGS. 16 to 18 are each a schematic cross-sectional view illustrating a step of the method of manufacturing the display panel according to an embodiment of the disclosure. In FIGS. 15 to 18, contents overlapping those described above with respect to FIGS. 3 to 12 will be omitted.

The method of manufacturing the display panel according to an embodiment of the disclosure may include preparing a preliminary display panel (S100), forming an organic layer OL on the preliminary display panel (S200), removing at least a portion of the organic layer OL adjacent to a heating line HL (S300), and forming a second electrode CE on the organic layer OL (S400).

FIG. 16 schematically illustrates preparing a preliminary display panel (S100) and forming an organic layer OL on the preliminary display panel (S200).

In the preparing of a preliminary display panel (S100), the preliminary display panel may include a base layer BL (see FIG. 4), a first electrode AE disposed on the base layer BL, a pixel defining film PDL disposed on the base layer BL (see FIG. 4) and having a pixel opening OP defined therein and corresponding to a pixel region PXA (see FIG. 4), and a heating line HL surrounding the pixel region PXA (see FIG. 4) in a plan view and disposed on the pixel defining film PDL.

FIG. 16 illustrates a step after the forming of the organic layer OL on the preliminary display panel (S200). The organic layer OL may include at least one light-emitting layer EML (see FIG. 4). For the convenience of description, FIG. 16 illustrates only components, which correspond to the light-emitting element layer DP-OLED, and a cross section of a region in which the heating line HL is disposed.

FIG. 17 schematically illustrates the removing of at least a portion of the organic layer OL (S300). The removing of at least a portion of the organic layer OL (S300) may be a step in which a pulse voltage is applied to the heating line HL so that the organic layer OL adjacent to the heating line HL is removed by generated heat.

In the removing of at least a portion of the organic layer OL (S300), only the organic layer OL adjacent to a partial region among the entire region of the heating line HL may be removed, or the organic layer OL adjacent to the entire region of the heating line HL may be removed. For example, as described above with respect to FIGS. 7A and 7B, only the organic layer OL adjacent to the first region P1-x of the heating line HL-x may be removed. For example, as described above with respect to FIGS. 9A and 9B, the organic layer OL adjacent to the entire region of the heating line HL-y may be removed.

The organic layer OL may include a first organic layer OL1 and a second organic layer OL2, and a manufacturing method of removing different ranges of the first and second organic layers OL1 and OL2 will be described below.

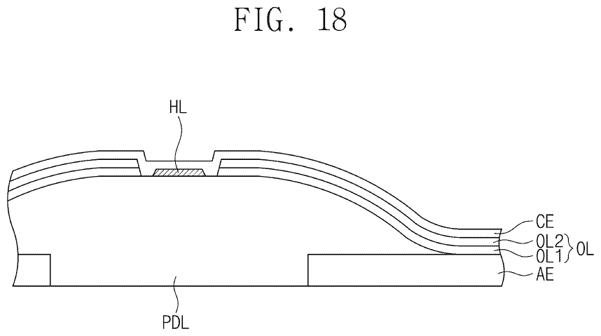

FIG. 18 schematically illustrates the forming of the second electrode CE on the organic layer OL (S400). In the forming of the second electrode CE on the organic layer OL (S400), the second electrode CE may be formed as a common layer, and a region, in which the heating line HL is exposed, may be covered by and electrically connected to the second electrode CE.

In an embodiment of the disclosure, as described above with reference to FIG. 7B, the heating line HL may include a first portion P1-x having a first width and a second portion P2-x having a second width greater than the first width. The removing of at least a portion of the organic layer OL (S300) may be removing the organic layer OL adjacent to the first portion P1-x of the heating line HL.

In an embodiment of the disclosure, the forming of the organic layer OL (S200) may include forming the first organic layer OL1 and forming the second organic layer OL2. The removing of at least a portion of the organic layer OL adjacent to the heating line HL (S300) may include removing the first organic layer OL1 adjacent to the heating line HL after the forming of the first organic layer OL1 and forming the second organic layer OL2 after the removing of the first organic layer OL1. After the second electrode CE is formed, a structure as illustrated in FIG. 8A may be formed.

In an embodiment of the disclosure, the removing of at least a portion of the organic layer OL adjacent to the heating line HL (S300) may be removing the entire organic layer OL adjacent to the heating line HL. The removing of all of the organic layer OL may mean that all of the first and second organic layers OL1 and OL2 adjacent to the heating line HL are removed. After the second electrode CE is formed, a structure as illustrated in FIG. 9A may be formed. For example, the second electrode CE may be formed to contact the heating line HL.

In an embodiment of the disclosure, the forming of the organic layer OL (S200) may include forming the first organic layer OL1 and forming the second organic layer OL2. The removing of at least a portion of the organic layer OL adjacent to the heating line HL (S300) may include removing the first organic layer OL1 adjacent to the heating line HL and removing the second organic layer OL2 adjacent to the heating line HL.

The removing of the first organic layer OL1 adjacent to the heating line HL may include applying a first pulse voltage after the forming of the first organic layer OL1. The forming of the second organic layer OL2 may be performed after the applying of the first pulse voltage. The removing of the second organic layer OL2 adjacent to the heating line HL may include applying a second pulse voltage after the forming of the second organic layer OL2. A pulse width of the first pulse voltage may be greater than a pulse width of the second pulse voltage. Accordingly, the removed region of the first organic layer OL1 removed by the first pulse voltage may be greater than the removed region of the second organic layer OL2 removed by the second pulse voltage. After the second electrode CE is formed, a structure as illustrated in FIG. 10A may be formed.

In an embodiment of the disclosure, as described above with reference to FIG. 11C, the heating line HL may include a first portion P1-z having a first width and a second portion P2-z having a second width greater than the first width. The forming of the organic layer OL (S200) may include forming the first organic layer OL1 and forming the second organic layer OL2. The removing of at least a portion of the organic layer OL adjacent to the heating line HL (S300) may include removing the first organic layer OL1 adjacent to the first and second portions P1-z and P2-z of the heating line HL and removing the second organic layer OL2 adjacent to the first portion P1-z of the heating line HL.

The removing of the first organic layer OL1 adjacent to the first and second portions P1-z and P2-z of the heating line HL may include applying a first pulse voltage after the forming of the first organic layer OL1, and the forming of the second organic layer OL2 may be performed after the applying of the first pulse voltage. The removing of the second organic layer OL2 adjacent to the first portion P1-z of the heating line HL may include applying a second pulse voltage after the forming of the second organic layer OL2. A voltage of the first pulse voltage may be higher than a voltage of the second pulse voltage. After the second electrode CE is formed, a structure illustrated in FIGS. 11A and 11B may be formed.

As described above, the display panel according to an embodiment of the disclosure may prevent a lateral leakage current, and therefore, a color mixing between adjacent pixels and poor luminance may be improved, thereby improving reliability.

The method of manufacturing the display panel according to an embodiment of the disclosure may efficiently remove the organic layer of the non-pixel region, thereby improving processability.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a pixel region and a non-pixel region adjacent to the pixel region; and
a light-emitting element layer disposed on a base layer, wherein
the light-emitting element layer comprises:
a first electrode disposed on the base layer;
a pixel defining film disposed on the base layer and having pixel openings corresponding to the pixel region;
a heating line disposed on the pixel defining film;
an organic layer comprising a light-emitting layer and disposed on the first electrode; and
a second electrode disposed on the organic layer, and
the heating line is disposed in the non-pixel region and surrounds the pixel region in a plan view.

2. The display panel of claim 1, wherein
the pixel region comprises:
a first pixel region; and
a second pixel region adjacent to the first pixel region, and
the first pixel region and the second pixel region are spaced apart from each other with the heating line interposed between the first pixel region and the second pixel region.

3. The display panel of claim 1, wherein
the heating line comprises:
a first portion having a first width; and
a second portion having a second width greater than the first width, and
the first portion of the heating line contacts and is electrically connected to the second electrode.

4. The display panel of claim 1, wherein
the organic layer comprises a first organic layer and a second organic layer disposed on the first organic layer, and
in a plan view, the heating line is spaced apart from the first organic layer and covered by the second organic layer.

5. The display panel of claim 1, wherein
in a plan view, the heating line is spaced apart from the organic layer, and
the heating line contacts and is electrically connected to the second electrode.

6. The display panel of claim 1, wherein
in a plan view, the heating line is spaced apart from the organic layer,
the heating line contacts and is electrically connected to the second electrode,
the organic layer comprises a first organic layer and a second organic layer disposed on the first organic layer, and
the first organic layer is covered by the second organic layer.

7. The display panel of claim 1, wherein
the heating line comprises a first portion having a first width and a second portion having a second width greater than the first width,
the organic layer comprises a first organic layer and a second organic layer disposed on the first organic layer,
the first portion of the heating line contacts and is electrically connected to the second electrode, and
in a plan view, the second portion of the heating line is spaced apart from the first organic layer and covered by the second organic layer.

8. The display panel of claim 7, wherein in a plan view, the first portion of the heating line is spaced apart from the first organic layer and the second organic layer.

9. The display panel of claim 1, wherein
the non-pixel region comprises:
a first region in which the heating line is disposed at a high density; and
a second region in which the heating line is disposed at a low density, and
the heating line disposed in the first region contacts and is electrically connected to the second electrode.

10. The display panel of claim 1, wherein the heating line comprises a metal.

11. The display panel of claim 1, wherein the base layer comprises a glass substrate or a silicon (Si) substrate.

12. The display panel of claim 1, wherein
a width of each of the pixel openings is in a range of about 1 μm to about 2 μm; and
a width of the heating line is in a range of about 0.1 μm to about 0.3 μm.

13. A method for manufacturing a display panel, the method comprising:
preparing a preliminary display panel including a pixel region and a non-pixel region adjacent to the pixel region and comprising a base layer, a first electrode disposed on the base layer, a pixel defining film disposed on the base layer and having pixel openings corresponding to the pixel region, and a heating line surrounding the pixel region and disposed on the pixel defining film;
forming an organic layer comprising a light-emitting layer on the preliminary display panel;
applying a voltage to the heating line and removing at least a portion of the organic layer adjacent to the heating line by generated heat; and
forming a second electrode on the organic layer.

14. The method of claim 13, wherein
the pixel region comprises:
a first pixel region; and
a second pixel region adjacent to the first pixel region, and
the first pixel region and the second pixel region are spaced apart from each other with the heating line interposed between the first pixel region and the second pixel region.

15. The method of claim 13, wherein
the heating line comprises a first portion having a first width and a second portion having a second width greater than the first width, and
the removing of the at least a portion of the organic layer comprises removing the organic layer adjacent to the first portion of the heating line.

16. The method of claim 13, wherein
the forming of the organic layer comprises forming a first organic layer and forming a second organic layer,
the removing of the at least a portion of the organic layer comprises removing at least a portion of the first organic layer adjacent to the heating line after the forming of the first organic layer, and
the forming of the second organic layer is performed after the removing of the at least a portion of the first organic layer.

17. The method of claim 13, wherein
the removing of the at least a portion of the organic layer comprises removing all of the organic layer adjacent to the heating line, and
after the forming of the second electrode, the second electrode contacts all of the heating line.

18. The method of claim 13, wherein
the forming of the organic layer comprises forming a first organic layer and forming a second organic layer,
the removing of the at least a portion of the organic layer comprises removing the first organic layer adjacent to the heating line and removing the second organic layer adjacent to the heating line,
the removing of the first organic layer comprises applying a first pulse voltage after the forming of the first organic layer;
the forming of the second organic layer is performed after the applying of the first pulse voltage,
the removing of the second organic layer comprises applying a second pulse voltage after the forming of the second organic layer, and
a pulse width of the first pulse voltage is greater than a pulse width of the second pulse voltage.

19. The method of claim 14, wherein:
the heating line comprises a first portion having a first width and a second portion having a second width greater than the first width,
the forming of the organic layer comprises forming a first organic layer and forming a second organic layer,
the removing of the at least a portion of the organic layer comprises removing the first organic layer adjacent to the first portion and the second portion of the heating line and removing the second organic layer adjacent to the first portion of the heating line,
the removing of the first organic layer adjacent to the first portion and the second portion of the heating line comprises applying a first pulse voltage after the forming of the first organic layer,
the forming of the second organic layer is performed after the applying of the first pulse voltage,
the removing of the second organic layer adjacent to the first portion of the heating line comprises applying a second pulse voltage after the forming of the second organic layer, and
a voltage of the first pulse voltage is higher than a voltage of the second pulse voltage.

20. The method of claim 13, wherein
the non-pixel region comprises a first region in which the heating line is disposed at a high density and a second region in which the heating line is disposed at a low density, and
the removing of the at least a portion of the organic layer comprises removing the organic layer adjacent to the heating line disposed in the first region.
